(19) United States
(12) Patent Application Publication
(10) Pub. No.: US 2019/0393247 A1
(43) Pub. Date: Dec. 26, 2019

(54) DISPLAY PANEL AND DISPLAY DEVICE WITH SAME

(71) Applicants: HKC CORPORATION LIMITED, Shenzhen, Guangdong (CN); CHONGQING HKC OPTOELECTRONICS TECHNOLOGY CO., LTD., Chongqing (CN)

(72) Inventor: Shishuai HUANG, Chongqing (CN)

(21) Appl. No.: 16/313,096

(22) PCT Filed: Nov. 14, 2018
(86) PCT No.: PCT/CN2018/115403

§ 371 Date: Dec. 24, 2018

(30) Foreign Application Priority Data
Jun. 22, 2018 (CN) 201810650701.8

(51) Int. Cl. H01L 27/12

(52) U.S. Cl. CPC H01L 27/124; H01L 27/1255

(57) ABSTRACT

A display panel includes: a first substrate including a display region and a wiring region disposed in the periphery of the display region, in which the wiring region has a fanout region; a second substrate arranged opposite to the first substrate; a transmission wiring circuit electrically coupled between a driving assembly and a plurality of signal lines; and an isolation layer disposed in a position of the second substrate relative to the position of the fanout region, in which an electrode layer is provided on the surface of the insulation layer, and the electrode layer is electrically coupled to a voltage line of a common electrode and the transmission wiring circuit to form a capacitor.

### CROSS-REFERENCE TO RELATED APPLICATIONS

The present application claims priority to Chinese Patent Application No. 2018106507018 filed on Jun. 22, 2018, entitled “display panel and display device with same”, the entire disclosure of which is incorporated herein by reference.

### BACKGROUND

### Technical Field

The present application relates to the technical field of wiring for a display panel, and particularly to a display panel and a display device with the same.

### Description of related art

The statements herein merely provide background information related to the present application and do not necessarily constitute the prior art. When the display panel is normally displayed, the gate drive circuit and the source drive circuit are required to combine the gate lines and the data lines interlaced on the substrate to control each pixel to realize image display.

The display driving mode includes: transmitting color (for example: R/G/B, Red/Green/Blue) compression signals, control signals and power source to the control panel through a system main board. After processed by a timing controller on the control panel, the signals are transmitted to the source circuit and the gate circuit of the printed circuit board, and the necessary data and power are transmitted to a display region through the gate lines, the data lines, the power source and the like on the substrate, such that the display obtains the power source, the signals required for presenting a frame. At present, the product frame in the market is getting narrower and narrower, and the space for wiring of a fanout region is becoming more and more limited. When the fanout region is small, the length difference between the outermost line and the middle line will become larger, and the difference in resistance will become larger, and the impedance such as the wiring cannot be achieved. At the same time, the parasitic capacitance above the outermost line and the middle line will also be different. The difference of the resistance and capacitance of the lines in the fanout region causes a delay in the resistance and capacitance of the signal transmitted to the source line through the two lines. This delay can cause problems such as unequal signals and signal delay in the fanout region. When the display panel is turned on and displays, there is also a problem of display difference with regionally uneven display.

### SUMMARY

An object of the present application is to provide a display panel, which includes, but is not limited to, the object of adjusting the phase shift signal delay of the fanout wiring.

In order to achieve the above object, the technical solutions adopted by the present application are that: a display panel, which includes:

a first substrate including a display region and a wiring region disposed at the periphery of the display region, wherein the wiring region has a fanout region, a plurality of signal lines are disposed in the display region, and a plurality of active switches and a plurality of pixel cells are disposed in the display region of the substrate, the plurality of pixel cells are respectively coupled to the plurality of active switches, and the plurality of active switches are electrically coupled to the plurality of signal lines respectively;

a second substrate arranged opposite to the first substrate;

a driving assembly disposed in the wiring region;

a transmission wiring circuit disposed in the fanout region, wherein the transmission wiring circuit is electrically coupled between the driving assembly and the plurality of signal lines; and

an isolation layer disposed at a position of the second substrate corresponding to the fanout region;

wherein an electrode layer is provided on the surface of the insulation layer, the electrode layer is electrically coupled to a voltage line of a common electrode, and the electrode layer and the transmission wiring circuit form a capacitor.

Another object of the present application is to provide a display panel, which includes:

a first substrate including a display region and a wiring region disposed in the periphery of the display region, wherein the wiring region has a fanout region, a plurality of signal lines are disposed in the display region, and a plurality of active switches and a plurality of pixel cells are disposed in the display region of the substrate, the plurality of pixel cells are respectively coupled to the plurality of active switches, and the plurality of active switches are electrically coupled to the plurality of signal lines respectively;

a second substrate arranged opposite to the first substrate;

a driving assembly disposed in the wiring region;

a transmission wiring circuit disposed in the fanout region, wherein the transmission wiring circuit is electrically coupled between the driving assembly and the plurality of signal lines, and the transmission wiring circuit has a connecting region and a slant-wiring region according to a shape arrangement of the fanout region, the wiring region is disposed between the slant-wiring region and the driving assembly, and the slant-wiring region is wired towards the display region in a narrow to wide manner and connects the plurality of signal lines;

wherein the position of the isolation layer corresponds to the position of the fanout region, the electrode layer is disposed on the surface of the insulation layer, the electrode layer on the insulation layer and the transmission wiring circuit form a capacitor, and the isolation layer is arranged to cover one of:

the fanout region,

the slant-wiring region,

the slant-wiring region and part of the connecting region, and

the connecting region and part of the slant-wiring region;

wherein the isolation layer includes at least one of a color resist layer and a black matrix.

Still another object of the present application is to provide a display device, which includes:

a first substrate including a display region and a wiring region disposed in the periphery of the display region, wherein the wiring region has a fanout region, a plurality of signal lines are disposed in the display region, and a plurality of active switches and a plurality of pixel cells are disposed in the display region of the substrate, the plurality of pixel cells are respectively coupled to the plurality of active switches, and the plurality of active switches are electrically coupled to the plurality of signal lines respectively;

a second substrate arranged opposite to the first substrate;

a driving assembly disposed in the wiring region; and a transmission wiring circuit disposed in the fanout region, wherein the transmission wiring circuit is electrically coupled between the driving assembly and the plurality of signal lines;

wherein the position of the isolation layer corresponds to the position of the fanout region, an electrode layer is provided on the surface of the insulation layer, and the electrode layer on the insulation layer and the transmission wiring circuit form a capacitor.

The display panel provided by the embodiments of the present invention can make the phase shift signal of the wiring have similar delays, and the problem of uneven wiring signals in the fanout region can be avoided through a capacitor above the wiring in the fanout region, without changing the existing production process.

### BRIEF DESCRIPTION OF THE DRAWINGS

In order to more clearly illustrate the technical solutions in the embodiments of the present application, the drawings used in the description of the embodiments or the prior art will be briefly described below. Obviously, the drawings in the following description are only some embodiments of the present application, and other drawings may be obtained based on these drawings for those of ordinaries skilled in the art without inventive work.

FIG. 1a is a schematic diagram of an architecture of an exemplary display device.

FIG. 1b is a schematic diagram of a configuration for an exemplary pixel cell.

FIG. 1c is a schematic diagram of wiring in a fanout region of an exemplary display device. FIG. 2a is a schematic diagram of wiring of the display panel provided by an embodiment of the present application.

FIG. 2b is a schematic diagram of wiring of the display panel provided by an embodiment of the present application.

FIG. 3a is a schematic diagram of wiring of the display panel provided by another embodiment of the present application.

FIG. 3b is a schematic diagram of wiring of the display panel provided by another embodiment of the present application.

FIG. 3c is a schematic diagram of wiring of the display panel provided by another embodiment of the present application.

FIG. 3d is a schematic diagram of wiring of the display panel provided by another embodiment of the present application.

FIG. 4a is a schematic diagram of wiring of the display panel provided by still another embodiment of the present application.

FIG. 4b is a schematic diagram of wiring of the display panel provided by still another embodiment of the present application.

FIG. 5a is a schematic diagram of wiring of the display panel provided by again another embodiment of the present application.

FIG. 5b is a schematic diagram of wiring of the display panel provided by again another embodiment of the present application.

FIG. 5c is a schematic diagram of wiring of the display panel provided by again another embodiment of the present application.

FIG. 5d is a schematic diagram of wiring of the display panel provided by again another embodiment of the present application.

FIG. 6 is a schematic diagram of wiring of the transmission wiring circuit of the display panel provided by again another embodiment of the present application.

### DETAILED DESCRIPTION

In order to make the objects, technical solutions and advantages of the present application more clear, the present application will be further described in detail below with reference to the drawings and embodiments. It should be understood that, the specific embodiments described herein are merely for explaining the present application, and not intended to limit the present application.

It should be noted that, when a component is referred to as “being fixed to” or “being arranged to” another component, the component may be directly on another component or indirectly on another component. When a component is referred to as “being connected to” another component, the component may be directly connected to another component or indirectly connected to another component. The orientation or position relationships indicated by the terms such as “on”, “below”, “left”, and “right” and the like are based on the orientation or position relationships shown in the accompanying drawings, and are used only for ease of illustration description, rather than indicating or implying that the mentioned apparatus or component must have a particular orientation or must be constructed or operated in a particular orientation. Therefore, such terms should not be construed as limiting of this patent. A person of ordinary skill in the art can understand the specific meaning of these terms according to specific situations. The terms “first”, “second” are merely for the object of describing, and should not be understood as indicating or implying the relative importance, or suggesting the amounts of the technical features. “a plurality of” means two or at least two unless otherwise specified.

In order to illustrate the technical solutions described in the present application, the present application will be described in detail with reference to specific drawings and embodiments.

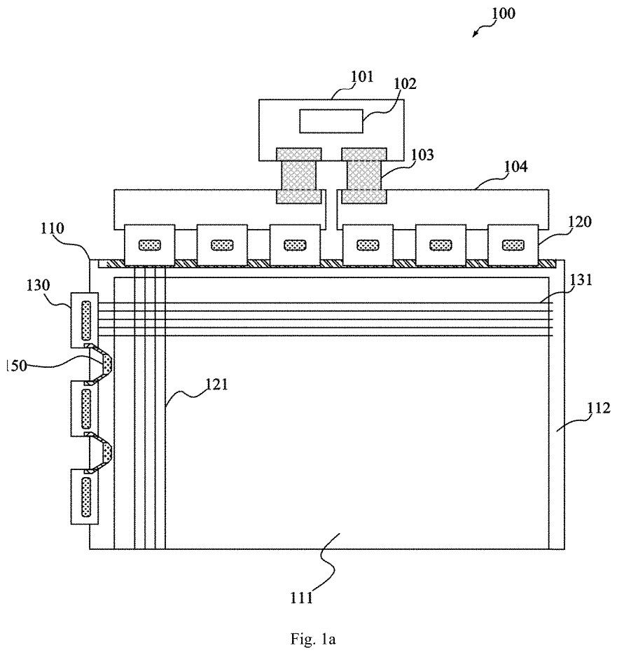

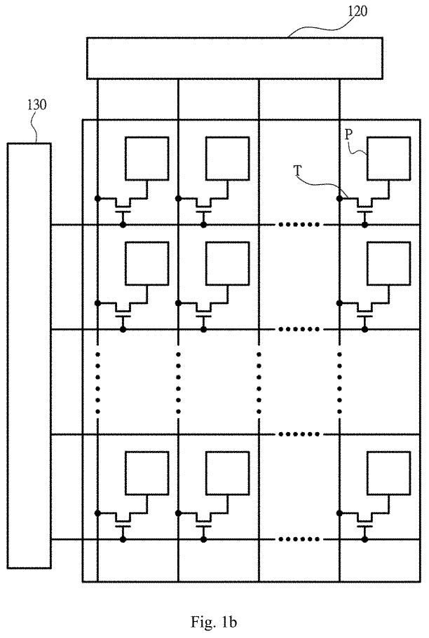

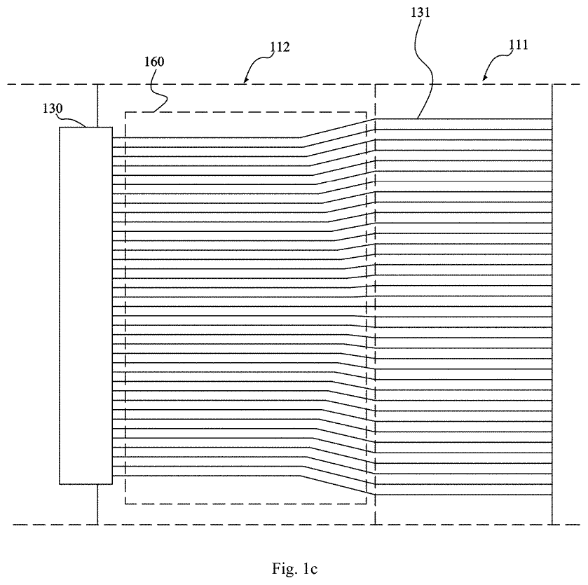

FIG. 1a shows a schematic diagram of an architecture of an exemplary display device. Referring to FIG. 1a, the display device 100 includes a control panel 101 including a timing controller (TCON) 102; a printed circuit board 104 connected to the control panel 101 through a flexible flat cable (FFC) 103; a source driving assembly 120 and a gate driving assembly 130 both disposed in a wiring region and respectively connected to source lines 121 and gate lines 131 in a display region 111. In some embodiments, the gate drives 130 and source drives 120 include, but are not limited to, a form of chip on film.

In an embodiment, the driving mode of the display device 100 includes: providing transmission of color (eg, R/G/B) compression signals, control signals, and power source to the control panel 101 through a system main board. After processed by the timing controller (TCON) 102 on the control panel 101, these signals together with the power source processed by the driving circuit are transmitted to the gate driving assembly 130 and the source driving assembly 120 of the printed circuit board 104 through the flexible flat cable (FFC). The gate driving assembly 130 and the source driving assembly 120 transmit necessary data and power source to the display region 111, thereby causing the display device 100 to obtain the power source and signals for presenting frames.

FIG. 1b shows a schematic diagram of a configuration for an exemplary pixel cell. Please cooperate with FIG. 1a to facilitate understanding. The gate driving assembly 130 provides a scan signal to the gate lines 131 row by row, and the scan signal is provided to one row of the gate lines 131 for a single scanning cycle. The source lines 121 of the display panel are opened row by row, and the source drive 120 provides data to the pixel cell P through the source lines 121.

FIG. 1c shows a schematic diagram of wiring in a fanout region of an exemplary display device, please cooperate with FIGS. 1a and 1b to facilitate understanding. In some embodiments, as shown in FIG. 1c, the gate driving assembly 130 and the source driving assembly 120 are arranged in a form of chip on film. The chip on film is provided with corresponding integrated circuits (IC), and the integrated circuits are electrically coupled to each other through a connecting circuit 150. In an embodiment, the integrated circuits are respectively connected to a conductive circuit in the display region 111 through a transmission wiring circuit 160 of the fanout region 112,. Depending on the integrated circuits, the connected conductive circuit is also different. For example, the gate integrated circuit is connected to the scan lines (the gate lines 131), and the source integrated circuit is connected to the data lines (the source lines 121).

However, when the fanout region 112 has a small space, the resistances of the middle lines of the transmission wiring circuit 160 is small, and as the distance of the middle lines increases, the resistances of the corresponding lines increase. Particularly, the length difference between outermost one line and middle one line of the transmission wiring circuit 160 is relatively larger, and the difference in resistance is also relatively larger, and the impedance such as the wiring cannot be achieved. At the same time, the parasitic capacitance of the outermost one line and the middle one line of the transmission wiring circuit 160 will also be different. The difference of the resistance and capacitance of the lines in the fanout region 112 causes a delay in the resistance and capacitance of the signal transmitted to the source lines through the two lines. This delay can cause problems such as unequal signals and signal delay in the fanout region. When the display panel is turned on and displays, there is also a problem of display difference with regionally uneven display.

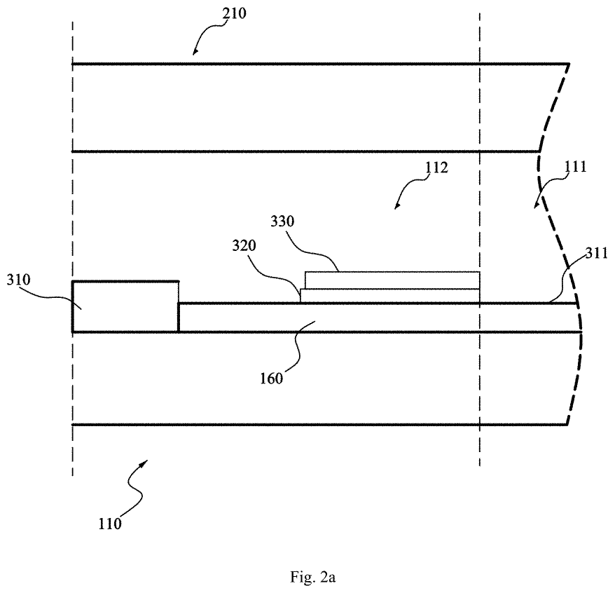

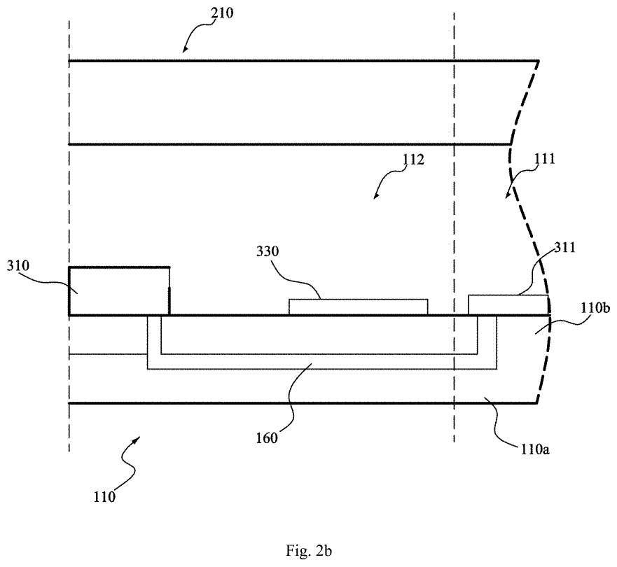

FIG. 2a shows a schematic diagram of wiring of the display panel in an embodiment of the present application. The component configuration of the display panel should be understood in conjunction with FIGS. 1a to 1c. Please refer to FIG. 2a, in an embodiment of the present application, a display panel includes: a first substrate 110 including a display region 111 and a peripheral wiring region of the display region 111, wherein the wiring region has a fanout region 112, and a plurality of signal lines 311 are disposed in the display region 111, and the display region 111 of the first substrate 110 is provided with a plurality of active switches T and a plurality of pixel cells P, and the plurality of pixel cells P are respectively coupled to the plurality of active switches T, and the plurality of active switches T are respectively electrically connected to the plurality of signal lines 311; a second substrate 210 disposed opposite to the first substrate 110; a driving assembly 310 disposed in the wiring region; a transmission wiring circuit 160 disposed in the fanout region 112, wherein the transmission wiring circuit 160 is electrically coupled to the driving assembly 310 and the plurality of signal lines 311; and an isolation layer 320 disposed above the transmission wiring circuit 160; wherein the surface of the isolation layer 320 is provided with an electrode layer 330, and the electrode layer 330 and the transmission wiring circuit 160 form a capacitor when the electrode layer 330 is electrically coupled to a shared voltage.

In an embodiment, the transmission wiring circuit 160 is arranged in such as a single metal wiring mode, and the electrode layer 330 is, for example, a metal layer or an indium tin oxide semiconductor layer, which are not limited here.

In an embodiment, the transmission line 160 includes a double-layer metal wiring mode, and the electrode layer 330 is, for example, an indium tin oxide semiconductor layer, which are not limited here.

In an embodiment, when the electrode layer 330 is a metal layer, it may be designed to be a single layer or a double layer metal layer or a metal oxide layer, which is not limited herein.

FIG. 2a shows a schematic diagram of wiring of the display panel in an embodiment according to the method of the present application. The component configuration of the display panel should be understood in conjunction with FIGS. 1a to 1c. Please refer to FIG. 2b, in an embodiment, the first substrate 110 is a multi-layer circuit board, and the first substrate 110 includes a first plate 110a and a second plate 110b, the transmission wiring circuit 160 is disposed on the surface of the first plate 110a, and the electrode layer 330 is disposed on the surface of the second plate 110b.

In an embodiment, the second plate 110b is the insulation layer 320.

In an embodiment, the configuration range of the electrode layer 330 locally or completely covers the wiring range of the transmission wiring circuit 160.

In an embodiment, the capacitance value of the capacitor corresponds to the range that the electrode layer 330 covers the transmission wiring circuit 160.

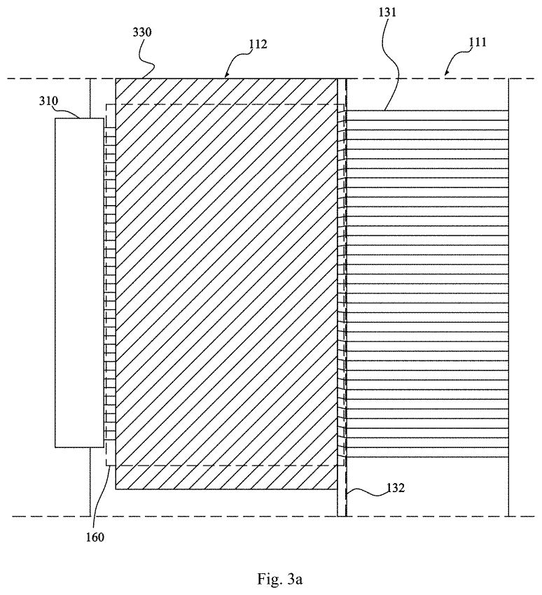

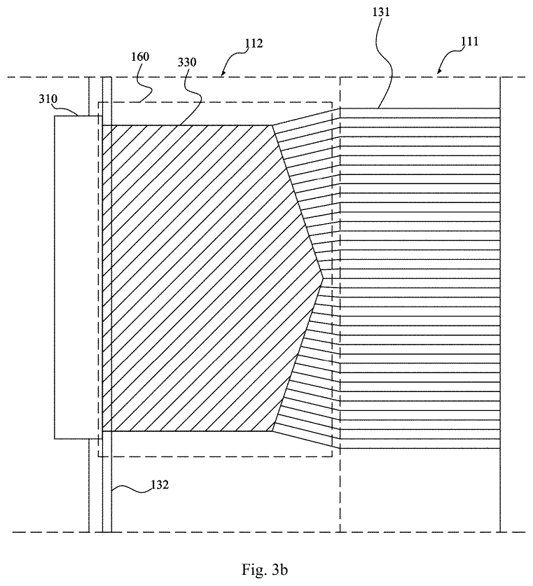

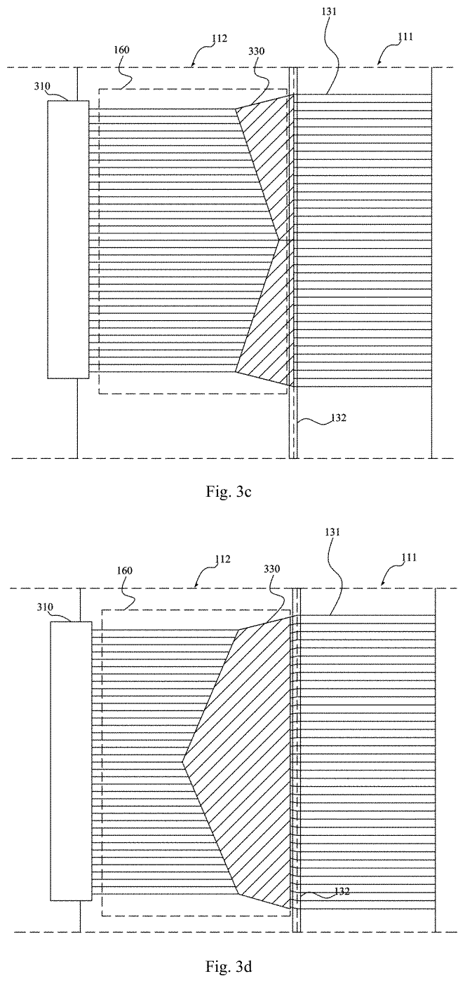

FIG. 3a shows a schematic diagram of wiring of the display panel in an embodiment of the present application. The component configuration of the display panel should be understood in conjunction with FIGS. 1a to 2b. Please refer to FIG. 3a, the electrode layer is configured to cover the entire wiring region such that the transmission wiring circuit 160 is covered within the range of the electrode layer.

FIG. 3b shows a schematic diagram of wiring of the display panel in an embodiment of the present application. The component configuration of the display panel should be understood in conjunction with FIGS. 1a to 2b. Please refer to FIG. 3b, the electrode layer 330 is configured to cover a connecting region.

FIG. 3c shows a schematic diagram of wiring of the display panel in an embodiment of the present application. The component configuration of the display panel should be understood in conjunction with FIGS. 1a to 2b. Please refer to FIG. 3c, the electrode layer 330 is configured to cover a slant-wiring region.

FIG. 3d shows a schematic diagram of wiring of the display panel in an embodiment of the present application. The component configuration of the display panel should be understood in conjunction with FIGS. 1a to 2b. Please refer to FIG. 3d, the electrode layer 330 is configured to cover the entire partial slant-wiring region and partial connecting region.

In an embodiment, the electrode layer 330 may be targeted only over the circuits of the wiring region.

In an embodiment, the electrode layer 330 is electrically coupled to a shared voltage line 132. As shown in FIG. 3b, when the electrode layer 330 is configured to cover the connecting region, the beginning of the connecting region is electrically coupled to the shared voltage line 132. As shown in FIG. 3c, when the electrode layer 330 is configured to cover the slant-wiring region, the ends of the slant-wiring region are electrically coupled to the shared voltage line 132.

In an embodiment, the plurality of signal lines 311 include the plurality of gate lines 131 and the plurality of source lines 121, and the driving assembly 310 includes at least one of the gate driving assembly 130 and the source driving assembly 120, in which the gate driving assembly 130 is electrically coupled to the plurality of gate lines 131, and the source driving assembly 120 is electrically coupled to the plurality of source lines 121.

In an embodiment, the present application provides a display panel, which includes: a first substrate 110 including a display region 111 and a peripheral wiring region of the display region 111, wherein the wiring region has a fanout region 112, and a plurality of signal lines 311 are disposed in the display region 111, and the display region 111 of the substrate is provided with a plurality of active switches T and a plurality of pixel cells P, and the plurality of pixel cells P are respectively coupled to the plurality of active switches T, and the plurality of active switches T are respectively electrically connected to the plurality of signal lines 311; a second substrate 210 disposed opposite to the first substrate 110; a driving assembly 310 disposed in the wiring region; a transmission wiring circuit 160 disposed in the fanout region 112, wherein the transmission wiring circuit 160 is electrically coupled to the driving assembly 310 and the plurality of signal lines 311, the transmission wiring circuit 160 has a connecting region and a slant-wiring region according to the shape arrangement of the fanout region 112, and the connecting region is disposed between the slant-wiring region and the driving assembly 310, the slant-wiring region is arranged towards the display region 111 in a narrow to wide manner and is connected the plurality of signal lines 311; and an isolation layer 160 disposed above the transmission wiring circuit 160; wherein the surface of the isolation layer 320 is provided with an electrode layer 330, and the electrode layer 330 and the transmission wiring circuit 160 form a capacitor when the electrode layer 330 is electrically coupled to a shared voltage, and the electrode layer 330 is configured to cover the fanout area 112, the connecting region, the slant-wiring region, or a partial slant-wiring region and partial connecting region.

In an embodiment of the present application, a display device 100 includes: a controller 101 configured to provide controlling signals and working voltages, wherein the working voltages include a shared voltage; and a display panel controlled by the controlling signals. The display panel includes: a first substrate 110 including a display region 111 and a peripheral wiring region of the display region 111, wherein the wiring region has a fanout region 112, and a plurality of signal lines 311 are disposed in the display region 111, and the display region 111 of the substrate is provided with a plurality of active switches T and a plurality of pixel cells P, and the plurality of pixel cells P are respectively coupled to the plurality of active switches T, and the plurality of active switches T are respectively electrically connected to the plurality of signal lines 311; a second substrate 210 disposed opposite to the first substrate 110; a driving assembly 310 disposed in the wiring region; a transmission wiring circuit 160 disposed in the fanout region 112, wherein the transmission wiring circuit 160 is electrically coupled to the driving assembly 310 and the plurality of signal lines 311; and an isolation layer 320 disposed above the transmission wiring circuit 160; wherein the surface of the isolation layer 320 is provided with an electrode layer 330, and the electrode layer 330 and the transmission wiring circuit 160 form a capacitor when the electrode layer 330 is electrically coupled to the shared voltage.

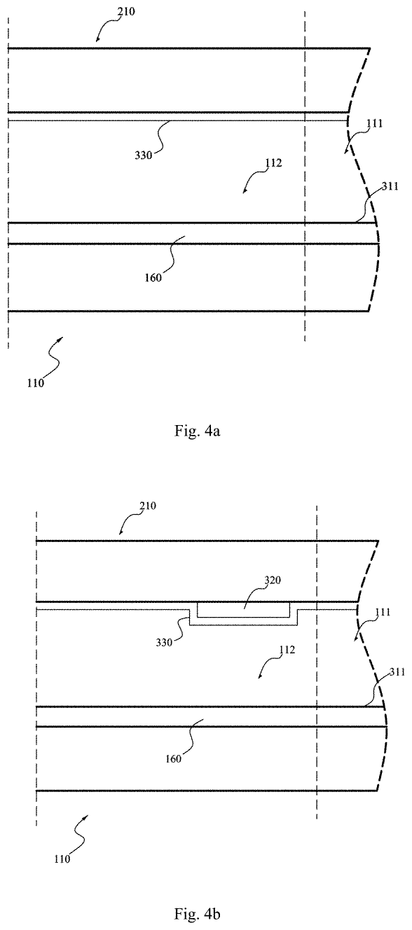

FIG. 4a shows a schematic diagram of wiring of the display panel in an embodiment of the present application. The component configuration of related display panel should be understood in conjunction with FIGS. 1a to 2b. Please refer to FIG. 4a, in an embodiment of the present application, a display panel includes: a first substrate 110 including a display region 111 and a peripheral wiring region of the display region 111, wherein the wiring region has a fanout region 112, and a plurality of signal lines 311 are disposed in the display region 111, and the display region 111 of the substrate is provided with a plurality of active switches T and a plurality of pixel cells P, and the plurality of pixel cells P are respectively coupled to the plurality of active switches T, and the plurality of active switches T are respectively electrically connected to the plurality of signal lines 311; a second substrate 210 disposed opposite to the first substrate 110; a driving assembly 310 disposed in the wiring region; a transmission wiring circuit 160 disposed in the fanout region 112, wherein the transmission wiring circuit 160 is electrically coupled between the driving assembly 310 and the plurality of signal lines 311; wherein a surface of the second substrate 210 corresponding to the fanout region 112 is provided with an electrode layer 330, and the electrode layer 330 and the transmission wiring circuit 160 form a capacitor.

In an embodiment, the transmission wiring circuit 160 is arranged in such as a metal wiring mode of a single layer or double layers, and the electrode layer 330 is, for example, a metal layer or an indium tin oxide semiconductor layer, which are not limited here.

FIG. 4b shows a schematic diagram of wiring of the display panel in an embodiment of the present application. The component configuration of related display panel should be understood in conjunction with FIGS. 1a to 1c, and FIG. 4c. Please refer to FIG. 4 b , in an embodiment, a position of the second substrate 210 corresponding to the fanout region 112 is provided with an isolation layer 320, and the electrode layer 330 is disposed on the surface of the isolation layer 320.

In an embodiment, the isolation layer 320 includes at least one of a color resist layer and a black matrix.

In an embodiment, the configuration range of the isolation layer 320 locally or completely covers the wiring range of the transmission wiring circuit 160.

In an embodiment, the capacitance value of the capacitor corresponds to the extent that the isolation layer 320 covers the transmission wiring circuit 160.

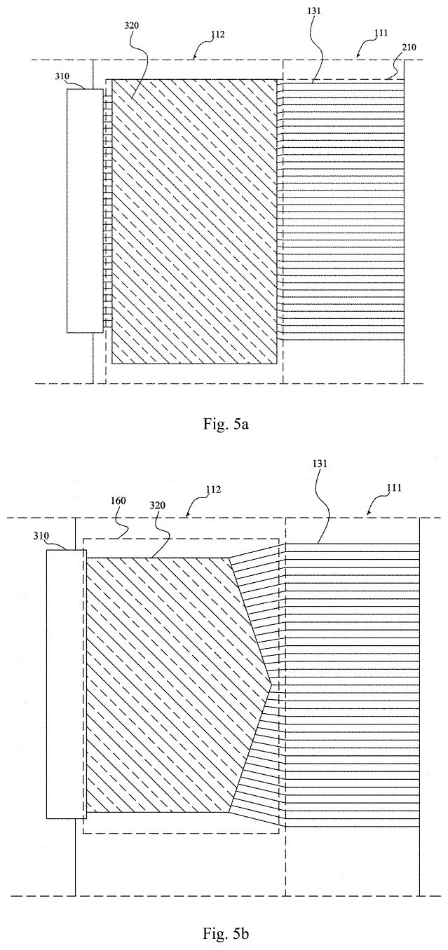

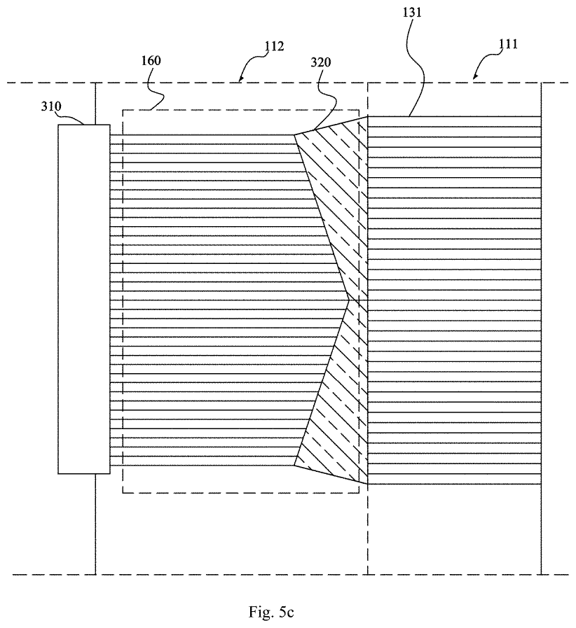

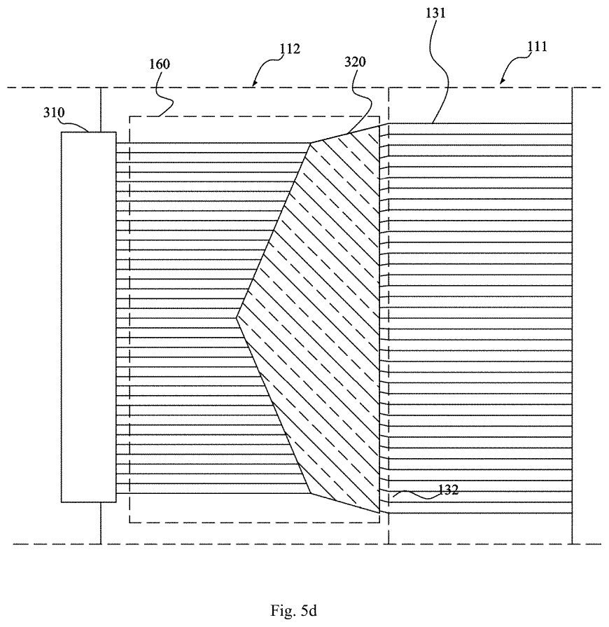

FIG. 5a shows a schematic diagram of wiring of the display panel in an embodiment of the present application. The component configuration of related display panel should be understood in conjunction with FIGS. 1a to 1c, and FIG. 4b. Please refer to FIG. 5a, the color resist layer 320 is configured to cover the entire fanout region such that the transmission wiring circuit 160 is covered within the range of the electrode layer disposed on the surface of the color resist layer.

FIG. 5b shows a schematic diagram of wiring of the display panel in an embodiment of the present application. The component configuration of related display panel should be understood in conjunction with FIGS. 1a to 1c, and FIG. 4b. Please refer to FIG. 5a, the color resist layer 320 is configured to cover the connecting region such that the connecting region is covered within the range of the electrode layer disposed on the surface of the color resist layer.

FIG. 5c shows a schematic diagram of wiring of the display panel in an embodiment of the present application. The component configuration of related display panel should be understood in conjunction with FIGS. 1a to 1c, and FIG. 4b. Please refer to FIG. 5c, the color resist layer 320 is configured to cover the slant-wiring region such that the slant-wiring region is covered within the range of the electrode layer 330 disposed on the surface of the color resist layer 320.

FIG. 5d shows a schematic diagram of wiring of the display panel in an embodiment of the present application. The component configuration of related display panel should be understood in conjunction with FIGS. 1a to 1c, and FIG. 4b. Please refer to FIG. 5d, the color resist layer 320 is configured to cover entire partial slant-wiring region and partial connecting region such that the partial slant-wiring region and the partial connecting region are covered within the range of the electrode layer 330 disposed on the surface of the color resist layer 320.

In an embodiment, the color resist layer 320 may be targeted only over the circuits of the wiring region 112.

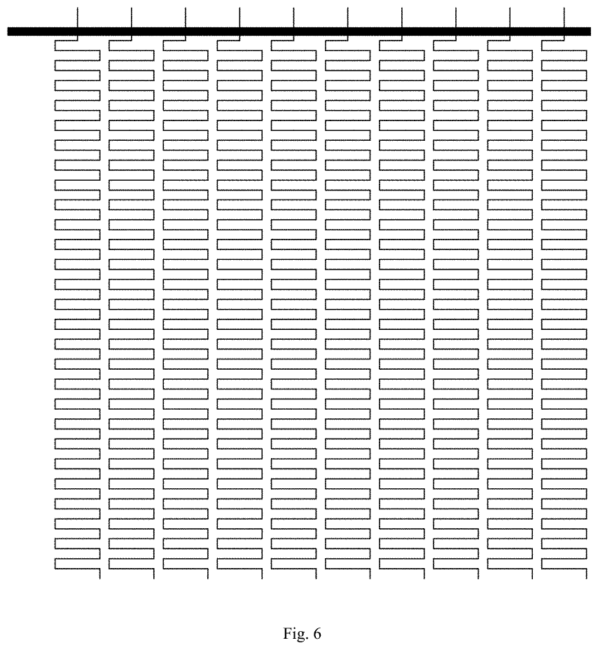

FIG. 6 is a schematic diagram of wiring of the transmission wiring circuit of the display panel in again another embodiment of the present application. As shown in FIG. 6, in an embodiment, the wiring of the connecting region is arranged in a continuously curved arch line.

In an embodiment, the display panel includes: a first substrate 110 including a display region 111 and a peripheral wiring region of the display region 111, wherein the wiring region has a fanout region 112, and a plurality of signal lines 311 are disposed in the display region 111, and the display region 111 of the substrate is provided with a plurality of active switches T and a plurality of pixel cells P, and the plurality of pixel cells P are respectively coupled to the plurality of active switches T, and the plurality of active switches T are respectively electrically connected to the plurality of signal lines 311; a second substrate 210 disposed opposite to the first substrate 110, wherein the second substrate is provided with an insulation layer 320; a driving assembly 210 disposed in the wiring region; a transmission wiring circuit 160 disposed in the fanout region 112, wherein the transmission wiring circuit 160 is electrically coupled to the driving assembly 310 and the plurality of signal lines 311, the transmission wiring circuit 160 has a connecting region and a slant-wiring region according to the shape arrangement of the fanout region 112, and the connecting region is disposed between the slant-wiring region and the driving assembly 310, the slant-wiring region is arranged towards the display region 111 in a narrow to wide manner and is connected the plurality of signal lines; wherein, the position of the isolation layer 320 corresponds to the position of the fanout region 112, the electrode layer 330 is disposed on the surface of the isolation layer 320, the electrode layer 330 on the surface of the isolation layer 320 and the transmission wiring circuit 160 form a capacitor, and the electrode layer 330 is configured to cover the fanout region 112, the slant-wiring region, or the slant-wiring region and the partial connecting region, or the connecting region and the partial slant-wiring region; wherein the isolation layer 320 includes at least one of a color resist layer and a black matrix.

In an embodiment of the present application, a display device 100 includes: a controller, which includes but is not limited to the foregoing control panel 101; and a display panel controlled by the controller, which includes: a first substrate 110 including a display region 111 and a peripheral wiring region of the display region 111, wherein the wiring region has a fanout region 112, and a plurality of signal lines 311 are disposed in the display region 111, and the display region 111 of the substrate is provided with a plurality of active switches T and a plurality of pixel cells P, and the plurality of pixel cells P are respectively coupled to the plurality of active switches T, and the plurality of active switches T are respectively electrically connected to the plurality of signal lines 311; a second substrate 210 disposed opposite to the first substrate 110, wherein the second substrate 210 is provided with an insulation layer 320; a driving assembly 210 disposed in the wiring region; a transmission wiring circuit 160 disposed in the fanout region 112, wherein the transmission wiring circuit 160 is electrically coupled to the driving assembly 310 and the plurality of signal lines 311; wherein the position of the isolation layer 320 corresponds to the position of the fanout region 112, the electrode layer 330 is disposed on the surface of the isolation layer 320, and the electrode layer 330 on the isolation layer 320 and the transmission wiring circuit 160 form a capacitor.

In an embodiment, the display panel further includes any of the previous embodiments.

In some embodiments, the display panel of the present application may be, for example, a liquid crystal display panel, but is not limited thereto, and may also be an OLED (Organic Light Emitting Diode) display panel, a W-OLED (White—Organic Light Emitting Diode) display panel, a QLED (Quantum Dot Light Emitting Diode) display panel, a plasma display panel, a curved display panel or other types of display panels.

In the present application, the capacitor above the wiring is fanned out, so that the phase shift signals of the wiring are delayed closely, and the problem of, for example, uneven signals in the fanout region can be avoided. Because there is no need to significantly adjust the production process, there is no special process requirements and difficulty, and it will not increase the high cost, and it is highly competitive in the market. Moreover, the present application is applicable to a variety of display panel designs of today, and of course also applies to the narrow frame design of the panel, meeting with the market and technology trends.

The above description is merely alternative embodiments of the present application, and is not intended to limit the present application. For those skilled in the art, the present application may has various variations and modifications. Any modification, equivalent substitution and improvement made within the spirit and principle of the present application, should be included in the scope of claims of the present application.

1. A display panel, comprising:
a first substrate comprising a display region and a wiring region at the periphery thereof, wherein the wiring region has a fanout region, with a plurality of signal lines being disposed in the display region;
a second substrate arranged opposite to the first substrate;
a driving assembly disposed in the wiring region;
a transmission wiring circuit disposed in the fanout region, wherein the transmission wiring circuit is electrically connected between the driving assembly and the plurality of signal lines; and
an isolation layer disposed at a position of the second substrate corresponding to the fanout region;
wherein an electrode layer is provided on the surface of the insulation layer, the electrode layer is electrically coupled to a common electrode voltage line, and wherein the electrode layer and the transmission wiring circuit form a capacitor.

2. The display panel according to claim 1, wherein the transmission wiring circuit includes a single layer of metal wiring, and the electrode layer is a metal layer.

3. The display panel according to claim 1, wherein the transmission wiring circuit includes a single layer of metal wiring, and the electrode layer is an indium tin oxide semiconductor layer.

4. The display panel according to claim 1, wherein the transmission wiring circuit includes double layers of metal wiring, and the electrode layer is a metal layer.

5. The display panel according to claim 1, wherein the transmission wiring circuit includes double layers of metal wiring, and the electrode layer is an indium tin oxide semiconductor layer.

6. The display panel according to claim 1, wherein the extension range of the insulation layer covers one of the following:
part wiring range of the transmission wiring circuit; and
all wiring range of the transmission wiring circuit.

7. The display panel according to claim 1, wherein the capacitance value of the capacitor corresponds to the range of the transmission wiring circuit covered by the insulation layer.

8. The display panel according to claim 1, wherein the capacitance value of the capacitor corresponds to the range of the transmission wiring circuit covered by the electrode layer.

9. The display panel according to claim 1, wherein the plurality of signal lines comprise a plurality of gate lines, the driving assembly comprises a gate driving assembly, and the gate driving assembly is electrically coupled to the plurality of gate lines.

10. The display panel according to claim 1, wherein the plurality of signal lines comprise a plurality of source lines, the driving assembly comprises a source driving assembly, and the source driving assembly is electrically coupled to the plurality of source lines.

11. The display panel according to claim 1, wherein the first substrate comprises a first plate and a second plate, the transmission wiring circuit is disposed on the surface of the first plate, and the electrode layer is disposed on the surface of the second plate.

12. The display panel according to claim 11, wherein the second plate is the isolation layer.

13. The display panel according to claim 1, wherein the configuration range of the electrode layer covers local or entire the wiring range of the transmission wiring circuit.

14. A display panel, comprising:
a first substrate including a display region and a wiring region disposed at the periphery of the display region, wherein the wiring region has a fanout region, a plurality of signal lines are disposed in the display region, and a plurality of active switches and a plurality of pixel cells are disposed in the display region of the substrate, the plurality of pixel cells are respectively coupled to the plurality of active switches, and the plurality of active switches are electrically coupled to the plurality of signal lines respectively;
a second substrate arranged opposite to the first substrate;
a driving assembly disposed in the wiring region;
a transmission wiring circuit disposed in the fanout region, wherein the transmission wiring circuit is electrically coupled between the driving assembly and the plurality of signal lines, and the transmission wiring circuit has a connecting region and a slant-wiring region according to a shape arrangement of the fanout region, the wiring region is disposed between the slant-wiring region and the driving assembly, and the slant-wiring region is wired towards the display region in a narrow to wide manner and connects the plurality of signal lines;
an isolation layer disposed on the second substrate, wherein the position of the isolation layer corresponds to the position of the fanout region;
wherein the electrode layer is disposed on the surface of the insulation layer, the electrode layer on the insulation layer and the transmission wiring circuit form a capacitor, and the isolation layer is arranged to cover one of:
the fanout region,
the slant-wiring region,
the slant-wiring region and part of the connecting region, and
the connecting region and part of the slant-wiring region;
wherein the isolation layer comprises at least one of a color resist layer and a black matrix.

15. The display panel according to claim 14, wherein the electrode layer is configured to cover the connecting region.

16. The display panel according to claim 14, wherein the electrode layer is configured to cover the slant-wiring region.

17. The display panel according to claim 14, wherein a circuit in the connecting region is arranged as a continuously curved arch line.

18. A display device, comprising:
a first substrate including a display region and a wiring region disposed in the periphery of the display region, wherein the wiring region has a fanout region, a plurality of signal lines are disposed in the display region, and a plurality of active switches and a plurality of pixel cells are disposed in the display region of the substrate, the plurality of pixel cells are respectively coupled to the plurality of active switches, and the plurality of active switches are electrically coupled to the plurality of signal lines respectively;
a second substrate arranged opposite to the first substrate;
a driving assembly disposed in the wiring region;
a transmission wiring circuit disposed in the fanout region, wherein the transmission wiring circuit is electrically connected to the driving assembly and the plurality of signal lines; and
an isolation layer disposed on the second substrate, wherein the position of the isolation layer corresponds to the position of the fanout region;
wherein an electrode layer is provided on the surface of the insulation layer, and the electrode layer on the insulation layer and the transmission wiring circuit form a capacitor.
